(19) United States
(12) Patent Application Publication
(10) Pub. No.: US 2013/0183581 A1
(43) Pub. Date: Jul. 18, 2013

(54) SUBSTRATE FOR ELECTRODE OF ELECTROCHEMICAL CELL

(71) Applicants: Subhash Dhar, Bloomfield Hills, MI (US); Fabio Albano, Royal Oak, MI (US); Srinivasan Venkatesan, Bloomfield Twp, MI (US); William Koetting, Davisburg, MI (US); Lin Higley, Troy, MI (US)

(72) Inventors: Subhash Dhar, Bloomfield Hills, MI (US); Fabio Albano, Royal Oak, MI (US); Srinivasan Venkatesan, Bloomfield Twp, MI (US); William Koetting, Davisburg, MI (US); Lin Higley, Troy, MI (US)

(73) Assignee: Energy Power Systems LLC, Troy, MI (US)

(21) Appl. No.: 13/350,505

(22) Filed: Jan. 13, 2012

(51) Int. Cl. H01M 4/73; C23C 14/34; C25D 5/00; H01B 5/14; C23C 16/50; C23C 4/12; C23C 16/48; H01B 5/00; H01M 4/68; B05D 5/12

(52) U.S. Cl. 429/211; 429/239; 205/80; 204/192.1; 205/261; 427/58; 427/569; 427/446; 427/585; 174/126.1; 174/126.2; 174/126.4

(57) ABSTRACT

An improved substrate is disclosed for an electrode of an electrochemical cell. The improved substrate includes a core material surrounded by a coating. The coating is amorphous such that the coating includes substantially no grain boundaries. The core material may be one of lead, fiber glass, and titanium. The coating may be one of lead, lead-dioxide, titanium nitride, and titanium dioxide. Further, an intermediate adhesion promoter surrounds the core material to enhance adhesion between the coating and the core material.

### RELATED APPLICATION(S)

This application incorporates by reference the entire disclosure of U.S. application Ser. No. 13/350,686 entitled, “Lead-Acid Battery Design Having Versatile Form Factor,” filed concurrently herewith by Subhash Dhar, et al.

### TECHNICAL FIELD

Embodiments of the present disclosure relate generally to electrochemical cells. More particularly, embodiments of the present disclosure relate to a design of a lead-acid electrochemical cell.

### BACKGROUND

Lead-acid electrochemical cells have been commercially successful as power cells for over one hundred years. For example, lead-acid batteries are widely used for starting, lighting, and ignition (SLI) applications in the automotive industry.

As an alternative to lead-acid batteries, nickel-metal hydride (“Ni-MH”) and lithium-ion (“Li-ion”) batteries have been used for hybrid and electric vehicle applications. Despite their higher cost, Ni-MH and Li-ion electro-chemistries have been favored over lead-acid electro-chemistry for hybrid and electric vehicle applications, due to their higher specific energy and energy density compared to lead-acid batteries.

While lead-acid, Ni-MH, and Li-ion batteries have each experienced commercial success, conventionally, each of these three types of electro-chemistries have been limited to certain applications. FIG. 8 shows a Ragone plot of various types of electrochemical cells that have been used in automotive applications, depicting their respective specific powers and specific energies compared to other technologies.

Lead-acid battery technology is low-cost, reliable, and relatively safe. Certain applications, such as complete or partial electrification of vehicles and back-up power applications, require higher specific energy than traditional SLI lead-acid batteries deliver. As shown in Table 1, lead-acid batteries suffer from low specific energy. This is primarily due to the weight of the components. Thus, there remains a need for low-cost, reliable, and relatively safe electrochemical cells for various applications that require high specific energy, including certain automotive and back-up power applications.

Lead-acid batteries have many advantages. First, they are a low-cost technology capable of being manufactured in any part of the world. Production of lead-acid batteries can be readily scaled up. Lead acid batteries are available in large quantities in a variety of sizes and designs. In addition, they deliver good high rate performance and moderately good low- and high-temperature performance. Lead-acid batteries are electrically efficient, with a turnaround efficiency of 75 to 80%, provide good “float” service (where the charge is maintained near the full-charge level by trickle charging), and exhibit good charge retention. Further, although lead is toxic, lead-acid battery components are easily recycled. An extremely high percentage of lead-acid battery components (in excess of 95%) are typically recycled.

Lead-acid batteries suffer from certain disadvantages as well. They offer relatively low cycle life, particularly in deep-discharge applications. Due to the weight of the lead components and other structural components needed to reinforce the plates, lead-acid batteries typically have limited energy density. If lead-acid batteries are stored for prolonged periods in a discharged condition, sulfation of the electrodes can occur, damaging the battery and impairing its performance. In addition, hydrogen can be evolved in some designs.

In contrast to lead-acid batteries, Ni-MH batteries use a metal hydride as the active negative material along with a conventional positive electrode such as nickel hydroxide. Ni-MH batteries feature relatively long cycle life, especially at a relatively low depth of discharge. The specific energy and energy density of Ni-MH batteries are higher than for lead-acid batteries. In addition, Ni-MH batteries are manufactured in small prismatic and cylindrical cells for a variety of applications and have been employed extensively in hybrid electric vehicles. Larger size Ni-MH cells have found limited use in electric vehicles.

The primary disadvantage of Ni-MH electrochemical cells is their high cost. Li-ion batteries share this disadvantage. In addition, improvements in energy density and specific energy of Li-ion designs have outpaced advances in Ni-MH designs in recent years. Thus, although nickel metal hydride batteries currently deliver substantially more power than designs of a decade ago, the progress of Li-ion batteries, in addition to their inherently higher operating voltage, has made them technically more competitive for many hybrid applications that would otherwise have employed Ni-MH batteries.

Li-ion batteries have captured a substantial share not only of the secondary consumer battery market but a major share of OEM hybrid and electric vehicle applications as well. Li-ion batteries provide high-energy density and high specific energy, as well as long cycle life. For example, Li-ion batteries can deliver greater than 1,000 cycles at 80% depth of discharge.

Li-ion batteries have certain advantages. They are available in a wide variety of shapes and sizes, and are much lighter than other secondary batteries that have a comparable energy capacity (both specific energy and energy density). In addition, they have higher open circuit voltage (typically ˜3.5 V vs. 2 V for lead-acid cells). In contrast to Ni—Cd and, to a lesser extent Ni-MH batteries, Li-ion batteries suffer no “memory effect,” and have much lower rates of self discharge (approximately 5% per month) compared to Ni-MH batteries (up to 20% per month).

Li-ion batteries, however, have certain disadvantages as well. They are expensive. Rates of charge and discharge above 1 C at lower temperatures are challenging because lithium diffusion is slow and it does not allow for the ions to move fast enough. Further, Li-ion batteries use liquid electrolytes to allow for faster diffusion rates, which results in formation of dendritic deposits at the negative electrode, causing hard shorts and resulting in potentially dangerous conditions. Liquid electrolytes also form deposits (referred to as an SEI layer) at the electrolyte/electrode interface, that can inhibit ion transfer and charge densification, indirectly causing the cell's rate capability and capacity to diminish over time due to increased capacitance effects. These problems can be exacerbated by high-charging levels and elevated temperatures. Li-ion cells may irreversibly lose capacity if operated in a float condition. Poor cooling and increased internal resistance cause temperatures to increase inside the cell, further degrading battery life. Most important, however, Li-ion batteries may suffer thermal runaway if overheated, overcharged, or over-discharged. This can lead to cell rupture, exposing the active material to the atmosphere. In extreme cases, this can cause the battery to catch fire. Deep discharge may short-circuit the Li-ion cell, causing recharging to be unsafe.

To manage these risks, Li-ion batteries are typically manufactured with expensive and complex power and thermal management systems. In a typical Li-ion application for a hybrid vehicle, two-thirds of the volume of the battery module may be given over to collateral equipment for thermal management and power electronics and battery management, dramatically increasing the overall size and weight of the battery system, as well as its cost.

In addition to the differing advantages and disadvantages of lead-acid, Ni-MH and Li-ion batteries, the specific energy, energy density, specific power, and power density of these three electro-chemistries vary substantially. Typical values for systems used in HEV-type applications are provided in Table 1 below.

TABLE 1

| Electro- | Specific | Volumetric | Specific |
|---|---|---|---|
| chemistry | Energy | Energy | Power |
| Type | Density (Whr/kg) | Density (Whr/l) | Density (W/kg) |
| Lead-Acid¹ | 30-50 Whr/kg | 60-75 Whr/l | 100-250 W/kg |
| Nickel Metal | 65-100 Whr/kg | 150-250 Whr/l | 250-550 W/kg |
| Hydride | | | |
| (Ni-MH)² | | | |
| Lithium-Ion | up to 131 Whr/kg | 250 Whr/l | up to 2,400 W/kg |
| (Li-ion)³ | | | |

¹http://en.wikipedia.org/wiki/Lead_acid_battery, accessed Jan. 11, 2012.
²Linden, David, ed., Handbook of Batteries, 3^{rd} Ed. (2002).
³http://info.a123systems.com/data-sheet-20ah-prismatic-pouch-cell, accessed Jan. 11, 2012.

Although both Ni-MH and Li-ion battery chemistries have claimed a substantial role in hybrid and electrical vehicles, both chemistries are substantially more expensive than lead-acid batteries for vehicular propulsion assist. The present inventors believe that the embodiments of the present disclosure can substantially improve the capacity of lead-acid batteries to provide a viable, low-cost alternative to Ni-MH and Li-ion electro-chemistries in all types of hybrid and electrical vehicle applications.

In particular, certain applications have proved difficult for Ni-MH and Li-ion batteries, such as certain automotive and standby power applications. Standby power application requirements have gradually been raised. The standby batteries of today have to be truly maintenance free, have to be low-cost, have long cycle-life, have low self-discharge, be capable of operating at extreme temperatures, and, finally, should have high specific energy and high specific power. Emerging smart grid applications to improve energy efficiency require high power, long life, and lower cost for continued growth in the market place.

Automobile manufacturers have encountered substantial consumer resistance in launching fleets of electric vehicles and hybrid vehicles, due to the increased cost of these vehicles relative to conventional automobiles powered by an internal combustion engine (“ICE”). Environmental and energy independence concerns have exerted greater pressures on manufacturers to offer cost-effective alternatives to internal combustion engine-powered vehicles. Although hybrids and electric vehicles can meet that demand, they typically rely on subsidies to defray the higher cost of the energy storage systems.

Table 2 below compares the application of various battery electro-chemistries and the internal combustion engine (ICE) and their current roles in certain automotive applications. As used in Table 2, “SLI” means starting, lighting, ignition; “HEV” means hybrid electric vehicle; “PHEV” means plug-in hybrid electric vehicle; “EREV” means extended range electric vehicle; and “EV” means electric vehicle.

TABLE 2

| | | | Power | | Mild | | | | |
|---|---|---|---|---|---|---|---|---|---|
| | SLI | Start/Stop | Assist | Regeneration | Hybrid | HEV | PHEV | EREV | EV |
| Pb- | ✓ | | | | | | | | |
| Acid | | | | | | | | | |
| Ni- | | | ✓ | ✓ | ✓ | ✓ | | | |
| MH | | | | | | | | | |
| Li- | | | ✓ | ✓ | ✓ | ✓ | ✓ | ✓ | ✓ |
| ion | | | | | | | | | |
| ICE | ✓ | ✓ | ✓ | ✓ | ✓ | ✓ | ✓ | ✓ | |

As shown in Table 2, there remains a need for specific applications in which partial electrification of the vehicle may provide environmental and energy efficiency advantages, without the same level of added cost associated with hybrid and electric vehicles using Ni-MH and Li-ion batteries. Even more specifically, there is a need for a low-cost, energy-efficient battery in the area of start/stop automotive applications.

Specific points in the duty cycle of an internal combustion engine entail far greater inefficiency than others. Internal combustion engines operate efficiently only over a relatively narrow range of crankshaft speeds. For example, when the vehicle is idling at a stop, fuel is being consumed with no useful work being done. Idle vehicle running time, stop/start events, power steering, air conditioning, or other power electronics component operation entail substantial inefficiencies in terms of fuel economy, as do rapid acceleration events. In addition, environmental pollution from a vehicle at these “start-stop” conditions is far worse than from a running vehicle that is moving. The partial electrification of the vehicle in relation to these more extreme operating conditions has been termed “micro” or “mild” hybrid applications, including start/stop electrification. Micro- and mild-hybrid technologies are unable to displace as much of the power delivered by the internal combustion engine as a full hybrid or electric vehicle. Nonetheless, they may be able to substantially increase fuel efficiency in a cost-effective manner without the substantial capital expenditure associated with full hybrid or full electric vehicle applications.

Conventional lead-acid batteries have not yet been able to fulfill this role. Conventional lead-acid batteries have been designed and optimized for the specific application of SLI operations. The needs of mild hybrid applications are different. A new process, design, and production process need to be developed and optimized for the mild hybrid application.

One need for a mild hybrid application is low-weight battery. Conventional lead-acid batteries are relatively heavy. This causes the battery to have a low specific energy due to the substantial weight of the lead components and other structural components that are necessary to provide rigidity to the plates. SLI lead-acid batteries typically have thinner plates, for the increased surface area that is needed to produce the power necessary to start the engine. But the grid thickness is limited to a minimum useful thickness because of the casting process and the mechanics of the grid hang. The minimum grid thickness is also determined on the positive electrode by corrosion processes. Positive plates are rarely less than 0.08″ (main outside framing wires) and 0.05″ on the face wires because of the difficulties of casting at production rates and, more importantly, concern over poor cycle-life issues. These parameters limit power. Lead-acid batteries designed for deeper discharge applications (such as motive power for forklifts) typically have heavier plates to enable them to withstand the deeper depth of discharge in these applications.

In typical lead-acid batteries, the active material is usually formed as a paste that is applied to the grid in order to form the plates as a composite material. Although the paste adheres well to itself, it does not adhere well to the grid materials because of paste shrinkage issues. This requires the use of grids that are more substantial and contain additional structural components to help support the active material, which, in turn, puts an extra weight burden on the cell.

Further, during the manufacture of conventional lead-acid batteries, the components are subjected to a number of mechanical stresses. A typical pasting operation involves applying the paste of active material onto the grid, which can stress the latticework of the grid. Expanded metal grids are lighter than cast grids, yet, the formation of the expanded grid itself introduces additional stress at each of the nodes of the expanded grid. These various structural materials, being subjected to substantial mechanical stresses during electrode pasting, handling, and cell operation, tend to corrode more readily in the acid-oxidizing environment of the battery after activation, especially when thin plates are used to increase power.

For example, cast and expanded metal grids have non-uniform stress during the life of the battery due to the molar volume change of converting the lead metal to PbO₂. This volume change of the corrosion product puts huge stress on the grids in a non-uniform manner because of the irregular cross-sectional shapes of the grid wires in cast and expanded metals.

Another need for a mild hybrid application is that rechargeable batteries should be able to be charged and discharged with less than 0.001% energy loss at each cycle. This is a function of the internal resistance of the design and the overvoltage necessary to overcome it. The reaction should be energy-efficient and should involve minimal physical changes to the battery that might limit cycle life. Side chemical reactions that may deteriorate the cell components, cause loss of life, create gaseous byproducts, or loss of energy should be minimal or absent. In addition, a rechargeable battery should desirably have high specific energy, low resistance, and good performance over a wide range of temperatures and be able to mitigate the structural stresses caused by lattice expansion. When the design is optimized for minimum resistance, the charge and discharge efficiency may dramatically improve.

Lead-acid batteries have many of these characteristics. The charge-discharge process is essentially highly reversible. The lead-acid system has been extensively studied and the secondary chemical reactions have been identified. And their detrimental effects have been mitigated using catalyst materials or engineering approaches. Although its energy density and specific energy are relatively low, the battery performs reliably over a wide range of temperatures, with good performance and good cycle life. A primary advantage of lead-acid batteries remains their low-cost.

A typical lead-acid electrochemical cell uses lead dioxide as an active material in the positive plate and metallic lead as the active material in the negative plate. These active materials are formed in situ. Typically, a charged positive electrode contains PbO₂. The electrolyte is sulfuric acid solution, typically about 1.2 specific gravity or 37% acid by weight. The basic electrode process in the positive and negative electrodes in a typical cycle involves formation of PbO₂/Pb via a dissolution-precipitation mechanism, causing non-uniform stresses within the positive electrode structure. The first stage in the discharge-charge mechanism is a double-sulfate formation reaction. Sulfuric acid in the electrolyte is consumed by discharge, producing water as the product. Unlike many other electrochemical systems, in lead-acid batteries the electrolyte is itself an active material and can be capacity-limiting.

In conventional lead-acid batteries, the major starting material is highly purified lead. Lead is used for the production of lead oxides for conversion first into paste and ultimately into the lead dioxide positive active material and sponge lead negative active material. Pure lead is generally too soft to be used as a grid material because of processing issues, except in very thick plates or spiral-wound batteries. Lead is typically hardened by the addition of alloying elements. Some of these alloying elements are grain refiners and corrosion inhibitors, but others may be detrimental to grid production or battery performance generally. One of the mitigating factors in the corrosion of lead/lead grids is the high hydrogen over-potential for hydrogen evolution on lead. Since most corrosion reactions are accompanied by hydrogen evolution as the cathode reaction, reduced hydrogen evolution will have an inhibiting effect on the anodic corrosion as well.

The purpose of the grid is to form the support structure for the active materials and to collect and carry the current generated during discharge from the active material to the cell terminals. Mechanical support can also be provided by non-metallic elements such as polymers, ceramics, and other components. But these components are not electrically conductive. Thus, they add weight without contributing to the specific energy of the cell.

Lead oxide is converted into a dough-like material that can be fixed to grids forming the plates. The process by which the paste is integrated into the grid is called pasting. Pasting can be a form of “ribbon” extrusion. The paste is pressed by hand trowel, or by machine, into the grid interstices. The amount of paste applied is regulated by the spacing of the hopper above the grid or the type of trowelling. As plates are pasted, water is forced out of the paste.

The typical curing process for SLI lead-acid plates is different for the positive and negative plates. Typically water is driven off the plate in a flash dryer until the amount of water remaining in the plate is between about 8 to 20% by weight. The positive plate is hydro-set at low temperature (<55 C+/−5 C) and high humidity for 24 to 72 hours. The negative plate is hydro-set at about the same temperature and humidity for 5 to 12 hours. The negative plate may be dried to the lower end of the 8 to 20% range and the positive plate to the upper end of the range. More recently, manufacturers use curing ovens where temperature and humidity are more precisely controlled. In the conventional process steps, the “hydro-set process” causes shrinkage of the “paste” active material that, in turn, causes it to break away from the grid in a non-uniform manner. The grid metal that is exposed is corroded preferentially and, since it is not in contact locally with the active material, results in increased resistance as well as formation, and life issues.

A simple cell consists of one positive and one negative plate, with one separator positioned between them. Most practical lead-acid electrochemical cells contain between 3 and 30 plates with separators between them. Leaf separators are typically used, although envelope separators may be used as well. The separator electrically insulates each plate from its nearest counter-electrode but must be porous enough to allow acid transport in or out of the plates.

A variety of different processes are used to seal battery cases and covers together. Enclosed cells are necessary to minimize safety hazards associated with the acidic electrolyte, potentially explosive gases produced on overcharge, and electric shock. Most SLI batteries are sealed with fusion of the case and cover, although some deep-cycling batteries are heat sealed. A wide variety of glues, clamps, and fasteners are also well-known in the art.

Typically, formation is initiated after the battery has been completely assembled. Formation activates the active materials. Batteries are then tested, packaged, and shipped.

A number of trade-offs must be considered in optimizing lead-acid batteries for various stand-by power and transportation uses. High-power density requires that the initial resistance of the battery be minimal High-power and energy densities also require the plates and separators be porous and, typically, that the paste density also be very low. High cycle life, in contrast, requires premium separators, high paste density, and the presence of binders, modest depth of discharge, good maintenance, and the presence of alloying elements and thick positive plates. Low-cost, in further contrast, requires both minimum fixed and variable costs, high-speed automated processing, and that no premium materials be used for the grid, paste, separator, or other cell and battery components.

A number of improvements have been made in the basic design of lead-acid electrochemical cells. Many of these have involved improvements in the characteristics of the substrate, the active material, as well as the bus bars or collector elements. For example, a variety of fibers or metals have been added to or embedded in the substrate material to help strengthen it. The active material has been strengthened with a variety of materials, including synthetic fibers and other additions. Particularly with respect to lead-acid batteries, these various approaches represent a trade-off between durability, capacity, and specific energy. The addition of various non-conductive strengthening elements helps strengthen the supporting grid but replaces conductive substrate and active material with non-conductive components.

In order to reduce the weight of the lead-acid electrochemical cells relative to their specific energy, various improvements have been disclosed. One approach has been to coat a light-weight, high-tensile strength fiber with sufficient lead to make a composite wire that could be used to support the grid of the electrode. Robertson, U.S. Pat. No. 275,859 discloses an apparatus for extrusion of lead onto a core material for use as a telegraph cable. Barnes, U.S. Pat. No. 3,808,040 discloses strengthening a conductive latticework to serve as a grid element by depositing strips of synthetic resin. Specifically, Barnes '040 patent discloses a lead-coated glass fiber. These approaches, however, have been unable to produce a material with sufficient properties of high-corrosion resistance and high-tensile strength to be able to fabricate a commercially viable lead-acid battery that can survive chemical attack from the electrolyte.

Blayner, et al., have disclosed further improvements in the composition of the substrate to reduce the weight of the electrodes and to increase the proportion of conductive material. Blayner, U.S. Pat. Nos. 5,010,637 and 4,658,623. Blayner discloses a method and apparatus for coating a fiber with an extruded, corrosion-resistant metal. Blayner discloses a variety of core materials that can include high-tensile strength fibrous material, such as an optical glass fiber, or highly-conductive metal wire. Similarly, Blayner discloses that the extruded, corrosion-resistant metal can be any of a number of metals such as lead, zinc, or nickel.

Blayner discloses that a corrosion-resistant metal is extruded through die. The core material is drawn through the die as the metal is extruded onto the core material. Continuous lengths of metal wire or fiber are coated with a uniform layer of extruded, corrosion-resistant metal. The wire is then used to weave a screen that acts as a substrate for the active material. There are no fusion points at the intersections of the woven wires. Electrodes may be constructed using such a screen as a grid with the active material being applied onto the grid. Rechargeable lead-acid electrochemical cells are constructed using pairs of electrodes.

Blayner discloses further improvements regarding the grain structure of the metal coating on the core material. In particular, Blayner discloses that the extruded corrosion-resistant metal has a longitudinally-oriented grain structure and uniform grain size. U.S. Pat. Nos. 5,925,470 and 6,027,822.

Fang, et al., disclose in their paper, Effect of Gap Size on Coating Extrusion of Pb-GF Composite Wire by Theoretical Calculation and Experimental Investigation, J. Mater. Sci. Technol., Vol. 21, No. 5 (2005), optimizing the gap in extruding lead-coated glass fiber. Although Blayner does not disclose the relationship between gap size and extrusion of the lead coated composite wire, Fang characterizes gap size as a key parameter for the continuous coating extrusion process. Fang reports that a gap between 0.12 mm and 0.24 mm is necessary, with a gap of 0.18 mm being optimal. Fang further reports that continuous fiber composite wire can enhance load and improve energy utilization.

The present inventors have found that, despite improvements in lead-acid electrochemical cells for automotive applications, prior known lead-acid batteries have not been able to achieve the same performance as Li-ion or Ni-MH cells for similar applications. There remains a need, therefore, for further improvements in the design and composition of lead-acid electrochemical cells to meet the specialized needs of the automotive and stand-by power markets. Specifically, there remains a need for a reliable replacement for lithium-ion electrochemical cells in certain applications that do not entail the same safety concerns raised by Li-ion electrochemical cells. Similarly, there remains a need for a reliable replacement for Ni-MH and Li-ion electrochemical cells with the added benefits of low-cost and reliability of lead-acid electrochemical cells. In addition, there remains a need for substantial improvement in battery production capacity to meet the growing needs of the automotive and stand-by power segments.

The United States Department of Energy (USDOE) has issued Corporate Average Fuel Efficiency (CAFE) guidelines for automotive fleets. Previously, SUVs and light trucks were excluded from the CAFE averages for motor vehicles. More recently, however, integrated guidelines have emerged specifying certain fuel efficiency standards for passenger vehicles, and light trucks, and SUVs. These guidelines require an average fuel efficiency of 31.4 miles per gallon by 2016. http://www.epa.gov/oms/climate/regulations/420r10009.pdf.

Anticipated improvements in internal combustion engine technology do not appear to be able to reach this goal. Similarly, the manufacturing capacity for pure hybrids and pure electric vehicles does not appear to be sufficient to enable fleets to reach this goal. Thus, it is anticipated that some combination of micro-hybrids or mild hybrids, in which electrochemical cells provide some of the power for either stop/start or certain acceleration applications, will be necessary in order to meet the CAFE standards.

Lead-acid battery systems may provide a reliable replacement for Li-ion or Ni-MH batteries in these applications, without the substantial safety concerns associated with Li-ion electro-chemistry and the increased cost associated with both Li-ion and Ni-MH batteries.

Further, the improved batteries of the present invention may be combined in hybrid systems with other types of electrochemical cells to provide electric power that is tailored to the unique automotive application. For example, a lead-acid battery of the present invention which features high-power can be combined with a Lithium-ion (“Li-ion”) or Nickel metal hydride (“Ni-MH”) electrochemical cell offering high energy, to provide a composite battery system tailored to the needs of the particular automotive stand-by or stationary power application, while reducing the relative sizes of each component.

### SUMMARY

Embodiments of the present disclosure include an improved substrate for an electrochemical cell. The improved substrate may include a core material that may be surrounded by a coating, and the coating may be amorphous such that the coating includes substantially no grain boundaries. Specifically, the coating may have one or more of microcrystalline, nano-crystalline, or amorphous structure, lacking long-range crystalline order.

The improved substrate may further include one or more of the following features, alone or in combination: the substrate may be an expanded metal sheet with a plurality of through-holes; the substrate may include a plurality of wires woven together to form a mesh-like structure, and each of the plurality of wires may include the core material surrounded by the coating; the core material may be selected from at least one of lead, fiber glass, and titanium; there may be an intermediate adhesion promoter layer surrounding the core material that may be configured to enhance adhesion between the coating and the core material; the coating may be a conductive coating selected from one of lead, lead dioxide, titanium nitride, and tin dioxide; and the substrate may be a screen configured to support and adhere to an active material.

Advantages of the disclosure will be set forth in part in the description which follows, and in part will be apparent from the description, or may be learned by practice of the disclosure. The objects and advantages of the disclosure will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one embodiments of the disclosure and together with the description, serve to explain the principles of the disclosure.

### BRIEF DESCRIPTION OF THE DRAWINGS

FIG. 1A is a schematic diagram of an exemplary expanded metal grid prior to expansion.

FIG. 1B is a schematic diagram of an exemplary expanded metal grid after expansion.

FIG. 2A is a cross-sectional view of the grid material of FIG. 1B, coated with a conductive lead coating consistent with one embodiment of the disclosure.

FIG. 2B is a cross-sectional view of the grid material of FIG. 1B having an intermediate coating and a conductive lead coating consistent with another embodiment of the disclosure.

FIG. 3 is a schematic diagram of an exemplary wire substrate woven into a grid.

FIG. 4A is a longitudinal cross-sectional view of an exemplary wire substrate used to form the exemplary grid of FIG. 3, the wire substrate having a conductive lead coating consistent with another embodiment of the disclosure.

FIG. 4B is a longitudinal cross-sectional view of an exemplary wire substrate used to form the exemplary grid of FIG. 3, the wire substrate having a conductive lead coating and an intermediate coating consistent with another embodiment of the disclosure.

FIG. 5A is a transverse cross-sectional view of an exemplary wire substrate used to form the exemplary grid of FIG. 3, the wire substrate having a conductive lead coating and an intermediate coating, consistent with another embodiment of the disclosure.

FIG. 5B is a transverse cross-sectional view of an exemplary wire substrate used to form the exemplary grid of FIG. 3, the wire substrate having a conductive lead coating, consistent with another embodiment of the disclosure.

FIG. 6 is a schematic diagram of an exemplary manufacturing system and process for making a wire substrate consistent with embodiments of the present disclosure.

FIG. 7 is a schematic diagram of an exemplary semi-circular electrode formed from a wire substrate consistent with the present disclosure, the electrode formed so as to exhibit relatively constant current density.

FIG. 8 shows Ragone plot of various types of electrochemical cells.

### DETAILED DESCRIPTION

Reference will now be made in detail to exemplary embodiments of the present disclosure, examples of which are illustrated in the accompanying drawings. Wherever possible, the same reference numbers will be used throughout the drawings to refer to the same or like parts.

Embodiments of the present disclosure generally relate to electrodes for a lead-acid electrochemical cell. Electrodes for lead-acid electrochemical cells typically are in the form of plates. The plates may include multiple components, including, but not limited to, separators, insulators, paste sheets, active material, and a substrate. The substrate may be the portion of the electrode that supports the active material, collects current, and aids in formulating energy and power of a lead-acid electrochemical cell. Accordingly, embodiments of the present disclosure relate to improved substrates for lead-acid electrochemical cells. Lead-acid electrochemical cells may form lead-acid batteries, which may be used in automobiles for energy storage to aid in increasing fuel efficiency, lead-acid storage batteries for stationary power applications, or any other suitable application.

More specifically, embodiments of the present disclosure may include improvements to the substrate for the plates of electrochemical cells to enable the creation of a lead-acid electrochemical cell with increased energy and power. In certain embodiments, energy and power of the lead-acid electrochemical cell may increase as a result of specific coatings on the substrate. The coatings may enhance adhesion between the substrate and active material, as well as increase surface conductivity and reduce corrosion of the plate. In addition, power (in W/kg or WA) of the lead-acid electrochemical cell may be increased by increasing current or reducing weight, such as increased porosity in active materials (reducing kg), increasing conductivity in the substrate and coatings (increasing W), better adhesion between substrates and active materials (reducing resistance, increasing W), thinner electrodes (increasing utilization per kg), and reduced current density (A/cm²).

Embodiments of the present disclosure may enable the use of lead-acid batteries in micro and mild-hybrid applications of vehicles, either alone or in combination with Ni-MH or Li-ion batteries. Embodiments of the present disclosure, however, are not limited to transportation and automotive applications. Embodiments of the present disclosure may be of use in any area known to those skilled in the art where use of electrochemical cells, and in particular lead-acid batteries, is desired, such as stationary power uses and energy storage systems for back-up power situations, as well as other battery applications.

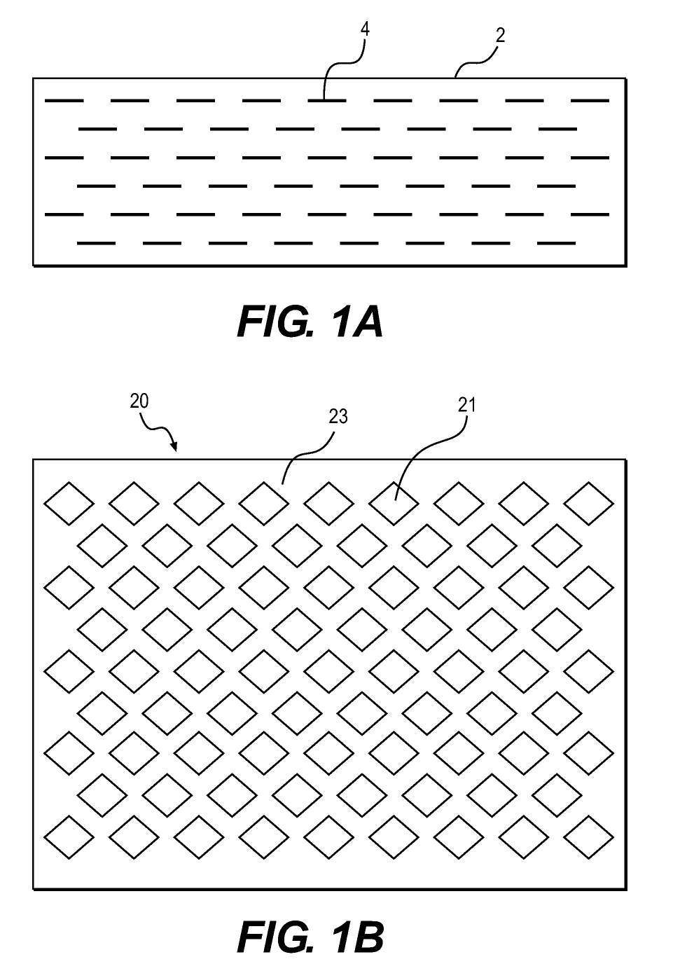

FIG. 1A depicts an exemplary substrate in its early stages of formation, consistent with one embodiment of the present disclosure. As shown in FIG. 1A, the substrate may be a metal sheet 2, which is perforated with a plurality of slits 4, so that, when the metal sheet 2 is expanded, it forms an expanded metal grid 20 as shown in FIG. 1B. The expanded metal grid 20 may include a plurality of diamond shaped apertures 21 formed therein as the metal sheet 2 is expanded. Expanded metal grid 20 may effectively consist of a plurality of elongate members 23 that bound the diamond shaped apertures 21, and make up the structure of the grid 20.

As will be described in more detail below, expanded metal grid 20 may be coated with a conductive coating of lead, forming a substrate for assembly of an electrode plate. The substrate may also serve as a current collector for the electrode plate. By forming the electrode from an expanded metal sheet 20, manufacturing costs and material use may be minimized. Moreover, the shape of expanded metal grid 20 may function as an effective substrate to which intermediate coatings, active material, or other coatings may be applied.

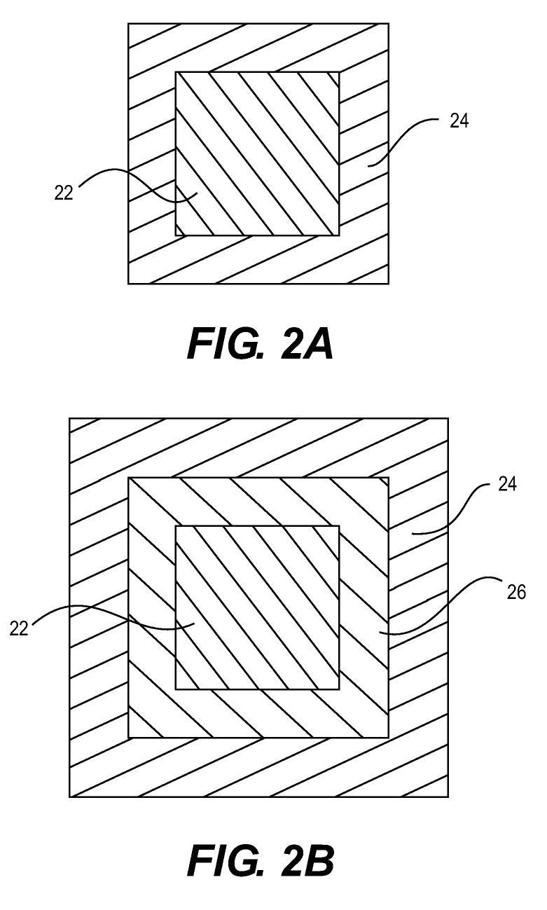

FIG. 2A depicts a cross-sectional view of one of the elongate members 23 that form the expanded metal grid 20. As shown in FIG. 2A, the elongate members 23 that form expanded metal grid 20 may include a core material 22 and a conductive lead coating 24. The core material 22 may be made from any suitable material selected for strength, light weight, and good compatibility with conductive lead coating 24. For example, the core material 22 may be selected from one or more of lead, titanium, or glass fiber. The conductive lead coating 24 may have a material structure that promotes conductivity, including without limitation, microcrystalline, nanocrystalline, or amorphous structure. In other words, the material structure of the conductive lead coating 24 may lack long range composition order and/or may lack grain boundaries.

In one embodiment, the core material 22 of expanded metal grid 20 may be made from a material selected from the group tantalum, tungsten, zirconium, and essentially titanium. The present inventors intend that a material be considered essentially titanium, in spite of the presence of inclusions, contaminants, or even alloying elements, providing these further amendments do not alter or modify the material properties of the titanium as used in the electrochemical cell. In one embodiment, the conductive coating 24 comprises a non-polarizing material. For example, the conductive coating 24 be made from a material selected from lead, lead dioxide, alpha lead dioxide, beta lead dioxide, titanium nitride, tin oxide, or silicon carbide. In addition, the conductive coating may be formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

In one embodiment, the core material 22 may selected from one or more of the following materials: fiberglass, carbon fiber, graphite, basalt fiber, silicon, silicon carbide, indium-tin-oxide, palladium, platinum, ruthenium, ruthenium oxide, rhodium, high-strength polypropylene, poly tetra fluoro-ethylene, conductive plastic fiber, and aromatic polyamide. In one embodiment, the core material 22 may be a metal or metal oxide that is electrically conductive, thermally stable, and chemically resistant.

FIG. 2B depicts another exemplary embodiment of the elongate members 23 of expanded metal grid 20. In particular, the elongate members may include a core material 22, an intermediate layer 26, and the conductive lead coating 24. The intermediate layer 26 may be selected based on its compatibility with core material 22 and conductive lead coating 24, and selected to enhance the bonding of the conductive lead coating 24 to the core material 22. One means of achieving good adhesion may include choosing a core material 22 that has similar mechanical properties to those of the conductive lead coating 24 and/or intermediate coating 26. For example, in one embodiment, core material 22 may be titanium and intermediate coating 26 may be lead dioxide, since titanium and lead dioxide have similar coefficients of thermal expansion.

For example, intermediate coating 26 may be a metal or metal oxide that is electrically conductive, thermally stable, and chemically resistant. For example, the conductive intermediate layer may be made from a material selected from palladium, platinum, ruthenium, ruthenium oxide, and rhodium. The conductive intermediate coating may be formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

As an alternative to expanded metal grid 20, the substrate may be a sheet of material having aligned, dimple-like spaces. The spaces may be punched, molded, or otherwise formed into the metal sheet. The spaces, like diamond shaped apertures 23, may accommodate and secure active material affixed to the resulting electrode. Accordingly, the substrate may include any configuration allowing for structural support of the active material.

A further alternative embodiment is to form a sandwich structure of either a single metal grid 20 or two metal grids 20, with a foil of conductive material disposed between the two grids or compressed into the grid(s). The grid and foil may be rolled together between rollers so that foil is located in the center of the grid and compressed into the grid. In certain embodiments, the grid may grip or bite into the lead foil, providing improved conductivity between the foil and the grid.

A conductive intermediate layer that is electrically conductive, thermally stable, and chemically resistant, may be disposed between the grid 20 and the conductive foil. If employed, the conductive intermediate layer may comprise one or more of palladium, platinum, ruthenium, ruthenium oxide, rhodium, or a non-polarizing material. The conductive intermediate layer is formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

The conductive foil may comprise lead.

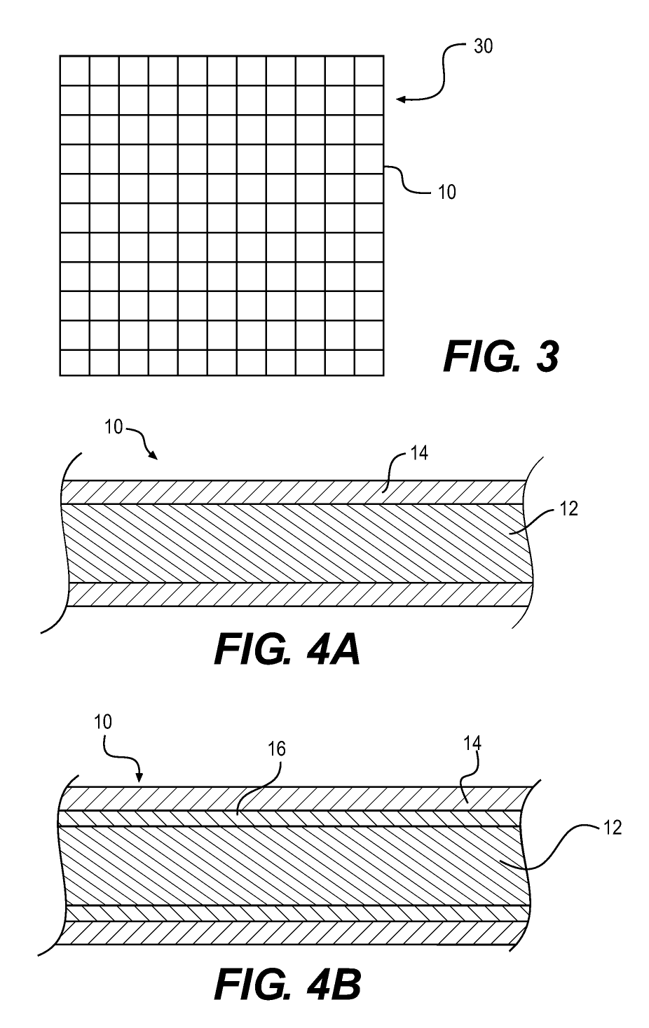

As yet another alternative to expanded metal grid 20, improved electrode substrates may be formed from a composite wire mesh or grid 30, as shown in FIG. 3. Wire grid 30 may be formed by weaving, fusing, molding, or otherwise manipulating an elongate composite wire 10 into the grid substrate. The process of making a wire grid 30 may include making a plurality of composite wires, each of which may be woven to form the mesh grid. Alternatively, the grid substrate may be formed by layering the plurality of wires in a criss-cross pattern and fusing them together with the application of heat. Alternatively, the mesh grid may be formed without fusing the wires at their crossing points. In one embodiment, the metal grid 30 may be made from a material selected from the group tantalum, tungsten, zirconium, and essentially titanium.

FIGS. 4A and 4B depict longitudinal cross-sections of an exemplary elongate composite wire 10, which can be assembled into the grid 30. As discussed above with respect to FIGS. 2A and 2B, the composite wire 10 may include a core material 12 and a conductive lead coating 14, as shown in FIG. 4A. The core material 12 may be made from any suitable material selected for strength, light weight, and good compatibility with conductive lead coating 14. For example, the core material 12 may be selected from one or more of lead, titanium, or glass fiber. The conductive lead coating 14 may have a material structure that promotes conductivity, including without limitation, microcrystalline, nanocrystalline, or amorphous structure. In other words, the material structure of the conductive lead coating 14 may lack long range compositional order and/or may lack grain boundaries. As a further embodiment, as shown in FIG. 4B, wire 10 may include an intermediate layer 16, which is selected to promote bonding of the conductive lead coating 14 to the core material 12. Core material 12 may be a fiber core, such as fiber glass, that provides sufficient strength to the substrate; and the coating 14 may be a lead coating, such as lead or lead-dioxide, providing sufficient corrosion resistance and conductivity to the lead composite wire.

Either of the composite wire 10 forming grid 30 or elongate members 23 forming sheet 20 may have any desired diameter and cross-sectional shape. For example, a wire having a fiber glass core may have a diameter of 5-35 nm. Alternatively, a wire having a carbon fiber core may have a diameter of 100-200 nm. In addition, in either embodiment, a lead coating may have a thickness of 10-30 micrometers.

Whether the substrate is formed as an expanded metal grid or a wire mesh, active material in the form of a paste may be applied to the substrate to form an electrochemical plate. The substrate may be any material that allows for sufficient strength and support of the active material, while including characteristics that improve power an energy of the lead-acid electrochemical cell. In addition, the substrate may be any material sufficiently compatible with the conductive lead coating to promote good adhesion.

In addition to lead, titanium, or glass fiber, core materials 12 or 22 may be formed of any suitable conductive material, including but not limited to, lead, copper, aluminum, carbon fiber, extruded carbon composite, carbon wire cloth, or any suitable polymeric compound known to those skilled in the art. Alternatively, the core material may be formed of a non-conductive material, including, but not limited to, fiberglass, optical fiber, polypropylene, high strength polyethylene, or fibrous basalt. Further, in addition to lead dioxide, intermediate coatings may include, but are not limited to, lead, titanium nitride, and tin dioxide. The thickness of the intermediate coating may depend on the type of conductive coating chosen. For example, if tin dioxide is used, the conductive coating may be a thin film. Alternatively, if lead dioxide or titanium nitride is used, the conductive coating may have a thickness between approximately 10 and 30 micrometers.

In certain embodiments, intermediate layer 16, 26 may be employed to promote adhesion between the core and the conductive coating. For example, an intermediate adhesion promoter may exist between the core and the conductive coating in order to increase the adhesive contact between core and conductive coating. The intermediate layer may include any suitable thickness in order to provide the desired adhesive contact between the core and conductive coating. The intermediate adhesion promoter may include, but is not limited to, lead-dioxide, tin-dioxide, Ebonex, carbon, and titanium-nitride. Similar to the conductive coating, the intermediate adhesion promoter may be chosen based on compatibility with the core material. For example, carbon may be chosen as intermediate adhesion promoter for a fiberglass core, and tin-dioxide, lead dioxide, Ebonex, or titanium nitride may be chosen as intermediate adhesion promoter for a titanium core.

Further, if lead dioxide is employed, alpha lead dioxide or beta lead dioxide may be employed to enhance adhesion (alpha) and conductivity (beta). Alternatively, the intermediate layer may comprise one or more of titanium nitride, tin oxide, and silicon carbide.

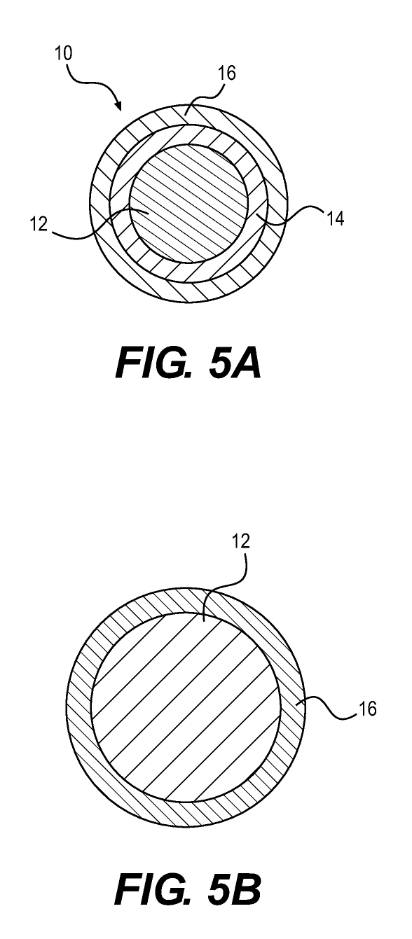

Composite wire 10 may further include any desired diameter sufficient to provide a substrate having suitable strength. For example, the diameter of a lead wire may be in the range of 45-80 nm. The wire also may include any suitable cross-sectional shape which allows for its use in the formation of sheet 20 or grid 30. Suitable cross-sectional shapes may include, but are not limited to, circular, oval, rectangular, or square. For example, FIGS. 5A and 5B illustrate wire 10 having a circular transverse cross-section. FIG. 5A shows the wire 10 having a circular core material 12, intermediate layer 16, and conductive lead coating 14. FIG. 5B shows the wire 10 having a circular core material 12 and conductive lead coating 14. In either embodiment, of FIG. 5A or 5B, the core material 12 and intermediate layer 16 may be made from any of the materials discussed above with respect to FIG. 2A-2B or 4A-4B.

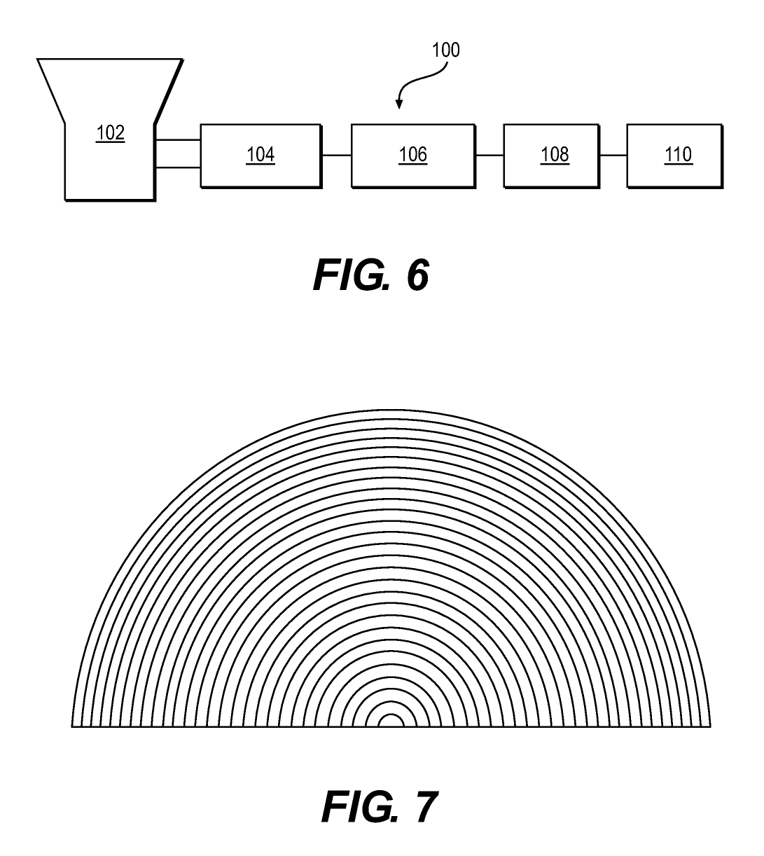

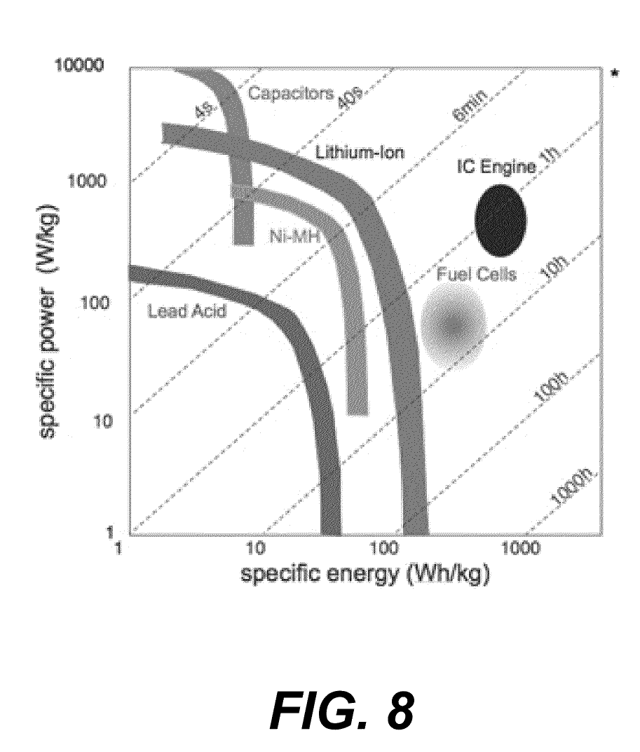

FIG. 6 depicts an embodiment of an exemplary system 100 for making a wire that can be formed into the substrate grid. Material that may be formed into the core may be placed into a metering device 102, such as a hopper. Core material may then be filtered and conveyed into a core-forming device 104. In one embodiment, core-forming device 104 may be one performing an extrusion process. The extrusion process may be enhanced with the use of ultrasonics and may include shaping the filtered material from the hopper into the core 12, 22, which may be an elongate member having a fixed cross-sectional profile. Shaping of the filtered material may include heating the material to achieve a malleable state and manipulating the heated material to achieve a desired thickness and length. Alternatively, the core-forming device may be one performing a wire drawing process known to those skilled in the art.

After shaping the core, if desired, the core may be coated with one or more intermediate adhesion promoters. Intermediate adhesion promoters be applied through any suitable coating process known to those skilled in the art. Thus, a coating machine 106 may be selected based on the material and/or the desired thickness of the intermediate adhesion promoter. For example, for thicker coats, the process may include, but is not limited to, thermal spraying, dipping, and painting. Alternatively, for thinner coats, the process may include, but is not limited to, sputtering or vacuum deposition. Further, a process may be used that can produce a variety of desired thicknesses of intermediate adhesion promoters, such as chemical vapor deposition (CVD). Moreover, when a conductive core material is chosen, it may be desired to apply an intermediate adhesion promoter through an electrochemical application, such as plating.

If an intermediate adhesion promoter is applied, wire may proceed through a drying machine 108 in order to prepare the wire for application of the conductive coating. Finally, the conductive coating may be applied in a similar manner as the intermediate adhesion promoter. As such, the conductive coating machine 110 may be determined by the properties of the conductive coating being applied and the desired thickness of the conductive coating. Accordingly, the conductive coating machine 110 may include, but is not limited to, a machine adapted for CVD, sputtering, dipping, painting, thermal spraying, and/or electrochemical application.

Application of conductive coating 14, 24 and/or intermediate layer 16, 26 to core 12 may be accomplished in a way that optimizes the particle size of the coating. Although the conductive lead coating and intermediate layer may have various grain structures and orientations and deliver satisfactory performance, performance may be enhanced by controlling the grain structure of the conductive lead coating and, potentially, of the intermediate layer as well. For example, a lead coating comprising microcrystalline, nanocrystalline or amorphous material may deliver superior performance due to its increased conductivity and resistance to corrosion. Smaller particle sizes may be considered in the range of approximately 10-50 nm. Processes that produce these smaller particle sizes may include, but are not limited to, ultrasonic spraying and plasma spraying.

Substrates having amorphous, microcrystalline, or nanocrystalline grain structures may provide a substrate with good corrosion resistance and adhesion to the active material. In some embodiments, the conductive materials that make up the substrate, however, may include crystalline grain structures.

Accordingly, it may be desired to heat treat either the composite wire 10, expanded grid 20, or grid 30 to produce the desired grain structure. Lead wire, or composite wire (either with or without an intermediate coating) or grid may proceed through a heat treatment process, such as annealing, which may transform the crystalline grain structure of the conductive lead coating 14, 24 into one or more of amorphous, microcrystalline, or nanocyrstalline grain structures. Annealing may be accomplished through heating, ultrasonic treatment, or any other appropriate means to produce the desired structure.

The active material may also be selected to enhance performance of the resulting electrochemical cell electrode. The sizes, shapes, and densities of particles of the active material may be chosen so as to increase the ability of the active material to transport gas out of the material without impairing the flow of electrolyte, which may thereby increase the capacity and catalytic activity of the electrode plates.

Application of active material to the substrate may include placement of both positive and negative active material to surfaces of the substrate. In one embodiment, active material may be applied in manner that may create a bi-polar design of the electrode. This may be accomplished by alternating positive and negative active material in each space on each side of the grid. Alternatively, in another embodiment, active material may be placed in a pseudo bi-polar design. The pseudo bi-polar design may be accomplished by the placement of both positive and negative active materials to alternating fields on the substrate. For example, pseudo bi-polar placement of active material may include, but is not limited to, the application of negative active material to one half of the substrate, along with the application of positive active material to the other half of the substrate as shown in FIG. 7. This pseudo bi-polar design may offer lower resistance and higher power of the lead-acid electrochemical cell. Further, it may enable the lead-acid electrochemical cell to operate at a lower temperature, which may reduce the need for collateral cooling equipment.

In yet additional embodiments, substrate and electrode plates may be formed in a semi-circular configuration. As depicted in FIG. 7, the mesh grid may be formed in a manner to provide a relatively constant current density by varying the distance between wires or current collector elements as one moves outward radially along the electrode plate.

Alternative embodiments of the disclosure will be apparent to those skilled in the art from consideration of the specification and practice of the invention disclosed herein. It is intended that the specification and examples be considered illustrative and exemplary only, with a true scope and spirit of the disclosure being indicated by the following claims.

What is claimed is:

1. An improved substrate of an electrode of an electrochemical cell, the substrate comprising:
a metal grid made from material selected from the group of tantalum, tungsten, zirconium, and consisting essentially of titanium;
a conductive coating applied to the surface of the metal grid, the conductive coating providing increased electrical conductivity and increased corrosion resistance to the metal grid.

2. The substrate of claim 1 wherein said conductive coating comprises a non-polarizing material, lead, or lead dioxide.

3. The substrate of claim 1 wherein said conductive coating comprises lead dioxide, and said lead dioxide comprises alpha lead dioxide or beta lead dioxide.

4. The substrate of claim 1 wherein said conductive coating comprises one or more of titanium nitride, tin oxide, or silicon carbide.

5. The substrate of claim 1 wherein said coating is formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

6. The substrate of claim 1 wherein said electrochemical cell is a lead-acid cell.

7. An improved electrode of an electrochemical cell, the electrode comprising:
a metal grid selected from the group tantalum, tungsten, zirconium, and consisting essentially of titanium;
a conductive intermediate layer formed on said metal grid;
a conductive coating formed on said conductive intermediate coating; and
an active material applied to said metal grid with said conductive intermediate layer and conductive coating to form the electrode.

8. The electrode of claim 7 wherein said intermediate layer is a metal or metal oxide that is electrically conductive, thermally stable, and corrosion resistant.

9. The electrode of claim 7 wherein said conductive intermediate layer comprises one or more of palladium, platinum, ruthenium, ruthenium oxide, rhodium, or a non-polarizing material.

10. The electrode of claim 7 wherein providing said conductive coating provides increased electrical conductivity and increased corrosion resistance relative to said uncoated metal grid.

11. The electrode of claim 7 wherein said conductive coating comprises lead or lead dioxide.

12. The electrode of claim 7 wherein said conductive coating comprises lead dioxide, and said lead dioxide coating comprises alpha lead dioxide or beta lead dioxide.

13. The electrode of claim 7 wherein said conductive coating comprises one or more of titanium nitride, tin oxide, and silicon carbide.

14. The electrode of claim 7 wherein said conductive intermediate coating is formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

15. The electrode of claim 7 wherein said conductive coating is formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

16. The electrode of claim 7 wherein said electrochemical cell is a lead-acid cell.

17. An improved electrode of an electrochemical cell, the electrode comprising:
a metal grid selected from the group tantalum, tungsten, zirconium, and consisting essentially of titanium;
a conductive foil;
said conductive foil being compressed into said conductive grid;
an active material applied to said conductive grid with said conductive foil to form the electrode.

18. The electrode of claim 17 further comprising a conductive intermediate layer that is electrically conductive, thermally stable, and corrosion resistant, disposed between said grid and said conductive foil.

19. The electrode of claim 18 wherein said conductive intermediate layer comprises one or more of palladium, platinum, ruthenium, ruthenium oxide, rhodium, or a non-polarizing material.

20. The electrode of claim 17 wherein said conductive foil comprises lead or lead dioxide.

21. The electrode of claim 18 wherein said intermediate layer comprises lead dioxide, and said lead dioxide coating comprises alpha lead dioxide or beta lead dioxide.

22. The electrode of claim 18 wherein said intermediate layer comprises one or more of titanium nitride, tin oxide, and silicon carbide.

23. The electrode of claim 18 wherein said conductive intermediate layer is formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

24. The electrode of claim 17 wherein said electrochemical cell is a lead-acid cell.

25. An improved wire for use in making an electrode of an electrochemical cell, the wire comprising:
conductive material resistant to corrosion in the electrochemical cell of any cross-sectional shape consisting essentially of lead having a microstructure lacking long-range order.

26. The wire of claim 25 wherein said lead wire comprises one or more of polycrystalline, nanocrystalline, microcrystalline or amorphous structure.

27. The wire of claim 25 wherein said lead wire further comprises a core of a second material.

28. The wire of claim 27 wherein said core comprises one or more of fiberglass, carbon fiber, graphite, basalt fiber, silicon, silicon carbide, indium-tin-oxide, palladium, titanium, titanium fiber, tantalum, tantalum fiber, tungsten, tungsten fiber, copper, copper fiber, zirconium, zirconium fiber, platinum, ruthenium, ruthenium oxide, rhodium, high-strength polypropylene, poly tetra fluoro-ethylene, conductive plastic fiber, or aromatic polyamide

29. The wire of claim 27 wherein said core comprises a metal or metal oxide that is electrically conductive, thermally stable, and chemically resistant.

30. The wire of claim 25 wherein said electrochemical cell is a lead-acid cell.

31. An improved electrode of an electrochemical cell, the electrode comprising:
a wire, of any cross-sectional shape, the wire comprising:
a core material;
a conductive intermediate layer applied to said core material; and
a conductive coating formed on said conductive intermediate layer;
a matrix formed from said wire to form a current collector; and
an active material applied to said matrix.

32. The electrode of claim 31 wherein said core comprises one or more of fiberglass, carbon fiber, graphite, basalt fiber, silicon, silicon carbide, indium-tin-oxide, palladium, titanium, titanium fiber, tantalum, tantalum fiber, tungsten, tungsten fiber, copper, copper fiber, zirconium, zirconium fiber, platinum, ruthenium, ruthenium oxide, rhodium, high-strength polypropylene, poly tetra fluoro-ethylene, conductive plastic fiber, and aromatic polyamide.

33. The electrode of claim 31 wherein said core comprises a metal or metal oxide that is electrically conductive, thermally stable, and corrosion resistant.

34. The electrode of claim 31 wherein said conductive intermediate layer is a metal or metal oxide that is electrically conductive, thermally stable, and corrosion resistant.

35. The electrode of claim 31 wherein said conductive intermediate layer comprises one or more of palladium, platinum, ruthenium, ruthenium oxide, rhodium, a non-polarizing material, lead, or lead dioxide.

36. The electrode of claim 31 wherein providing said conductive coating provides increased electrical conductivity and increased corrosion resistance relative to an uncoated metal grid.

37. The electrode of claim 31 wherein said conductive coating further comprises lead having a microstructure lacking long-range order.

38. The electrode of claim 31 wherein said conductive coating comprises lead dioxide, and said lead dioxide coating comprises alpha lead dioxide or beta lead dioxide.

39. The electrode of claim 31 wherein said conductive coating comprises one or more of titanium nitride, tin oxide, or silicon carbide.

40. The electrode of claim 31 wherein said conductive intermediate coating is formed by one or more of the techniques of electroplating, electro-winning, electroless deposition, dip coating, spraying, plasma spraying, physical vapor deposition, ion-assisted physical vapor deposition, chemical vapor deposition, plasma enhanced chemical vapor deposition, or sputtering.

41. The electrode of claim 31 wherein said conductive coating is formed by one or more of the techniques of electroplating, electrowinning, electroless deposition, dip coating, spraying, plasma spraying, physical vapor deposition, ion-assisted physical vapor deposition, chemical vapor deposition, plasma enhanced chemical vapor deposition, or sputtering.

42. The electrode of claim 31 wherein said electrochemical cell is a lead-acid cell.
